(19) United States
(12) Patent Application Publication
(10) Pub. No.: US 2018/0005956 A1
(43) Pub. Date: Jan. 4, 2018

(54) Electronic Circuit and Substrate with Identification Pattern for Separate Electronic Circuits and Method for Producing Thereof

(71) Applicant: C-MAC Electromag bvba, Ronse (BE)

(72) Inventor: Wim Degraeve, Kluisbergen (BE)

(21) Appl. No.: 15/637,243

(22) Filed: Jun. 29, 2017

(30) Foreign Application Priority Data
Jun. 29, 2016 (BE) 2016/5505

(51) Int. Cl. H01L 23/544; H01L 23/498; H01L 21/48; H01L 23/00; H01L 23/13; H01L 23/373

(52) U.S. Cl. CPC H01L 23/544; H01L 23/562; H01L 23/13; H01L 23/49838; H01L 21/4846; H01L 23/3735; H01L 2223/54413; H01L 2223/54433; H01L 2223/54493

(57) ABSTRACT

The present invention relates to an improved electronic circuit, as well as an improved substrate with electronic circuits, with an identification pattern. The invention makes it possible to make them identifiable and amongst other things to retrace the circuit(s) in this way through the production process. Furthermore, the invention relates to an improved production method for circuits and substrates according to the invention.

### TECHNICAL DOMAIN

The invention relates to an improved electronic circuit that can be identified in a simple way and that can be traced to earlier production processes, as well as relates to substrates comprising several of these electronic circuits. Additionally, a method is described for applying the identification patterns, and thus producing the circuits and substrates.

### STATE OF THE ART

In the mass production of electronic circuits, especially in case of highly performing components, it is of crucial importance that a producer can trace back the production process for a specific circuit as precise as possible. This is for example the case with production error, in which case the producer is possibly obliged to, but surely also important to avoid future errors, to know where the problems occurred at the production (which units handled the faulty circuit, which material had been used—batch, supplier and similar, which operator, . . . ). In this way, based thereupon, also other circuits can be checked where possible errors are present. Consumers and producers also ever more require such a ‘traceability’, especially if it is about high-end products for which a minimum percentage defective is allowed. Moreover, by providing this increased quality control, an especially low percentage defective can be provided to consumers, which is very important in particular markets, especially in the tender procedure, and especially risks for end consumers are strongly reduced. Typically, electronic circuits are produced (and also sold) in so-called panels, with thereupon a number (whether or not identical) circuits, that can be singulated in a following production process. Hereby, it should be remarked that, by making the circuits separately identifiable, it is possible to store a large amount of information about the production processes at the production of the circuit, that, in case of failure, can provide interesting information to avoid or reduce such problems in the future. As said, this information can amongst other things relate to choices of material, environmental parameters, production parameters and others.

The present solutions of these problems are typically insufficient or impractical, and will moreover also often be time-consuming at the production and possible entail extra costs. The electronic circuits of an identification component (for example RFID tag) can for example be provided for, by means of which the characteristics of the electronic circuit can be retrieved. However, this is an extra component, which increases the price and moreover also takes space at the circuit, which is undesired considering the ever-increasing miniaturization. Moreover, they can also become damaged (particularly in case of damage to the circuit itself) and can in this way also not deliver any relevant information any more. For this reason and others, the applicant has looked for more efficient and simple ways to make electronic circuits identifiable.

The present invention aims to find a solution for at least some of the above-mentioned problems. The invention aims to solve the problems by making use in an inventive way of tensile stress-reducing indentations on the circuit and by applying these per circuit in a pattern by means of which the circuit can be identified.

### SUMMARY OF THE INVENTION

The invention relates in a first aspect to an electronic circuit, preferably a directly bonded copper (DBC) ceramic substrate circuit for use in power electronics, comprising:
a. a substantially flat, ceramic support layer;
b. a metal layer at at least one side, preferably at both sides, of the ceramic support layer;
   in which at least one metal layer is provided with one or more dimples in the metal layer along at least one edge of the metal layer, in which the dimples are adapted for at least partially reducing tensile forces in the metal layer;
   characterized in that the one or more dimples form an identification pattern. Preferably, the identification pattern distinguishes the electronic circuit in a unique way from other electronic circuits. Note that these ‘other electronic circuits’ can refer to the other electronic circuits in the same substrate, or to all electronic circuits of this type, or more generally even to all electronic circuits.

In a second aspect, the invention relates to a substrate, preferably for use in power electronics, comprising:
a. a substantially flat, ceramic support layer comprising at least two separate electronic circuits that are connected along a weakened break line;
b. a metal layer on the separate electronic circuits at at least one side, preferably at both sides, of the ceramic support layer, in which the metal layer of the separate electronic circuits are separated along the break lines;
   in which one metal layer of at least one, preferably each, of the electronic circuits of the substrate is provided with one or more dimples in the metal layer along at least one edge of the metal layer, in which the dimples are adapted for at least partially reducing tensile forces in the metal layer;
   characterized in that the one or more dimples per electronic circuit form an identification pattern. Preferably, in which the identification pattern distinguishes the electronic circuit in a unique way from at least the other electronic circuits of the substrate.

Preferably, it relates to a substrate comprising several of the above-mentioned electronic circuits. The generality of a substrate with several electronic circuits will not be discussed in more detail here, as they can be considered as part of the state of the art and thus implicitly are part of the present document.

In a following aspect, the invention relates to a method for applying tensile force-reducing identification patterns on a metal layer of a substrate, in which the substrate comprises a multitude of electronic circuits, comprising the following steps:
a. providing the substrate, in which the electronic circuits comprise a metal layer at at least one side of a ceramic flat support layer;
b. applying one or more dimples in the metal layer along at least one edge of the metal layer, in which the dimples are adapted for at least partially reducing tensile forces in the metal layer;
   characterized in that the one or more dimples are applied in an identification pattern;
c. coupling the electronic circuits to the applied identification pattern in a central server.

Preferably, the identification pattern distinguishes the electronic circuit in a unique way from at least the other electronic circuits of the substrate.

In a following aspect, the invention relates to a method for the improved production of substrates with a multitude of electronic circuits, in which the circuits comprise a metal layer at at least one side of a ceramic flat support layer:
a. producing the substrate along a production line with one or more production devices, in which the substrate is produced with one or more raw materials from identifiable batches of the one or more raw materials;
b. applying a tension-reducing identification pattern on a metal layer of the substrate according to the method described above;
c. centrally storing information relating to the production line and/or the production devices and/or the identifiable batch of the raw materials, that are used in the step of producing the substrate.

### DESCRIPTION OF THE FIGURES

FIG. 1 shows a possible front side of a substrate with a multitude of electronic circuits.

FIG. 2 shows a possible front side of an electronic circuit with tension reducing dimples in the metal layer.

FIG. 3 shows a possible rear side of a substrate with a multitude of electronic circuits, provided with identification patterns.

FIG. 4 shows an enlarged rear side of the substrate of FIG. 3 with a multitude of electronic circuits, provided with identification patterns.

FIG. 5 shows a possible front side of an electronic circuit with tension reducing dimples in the metal layer.

FIG. 6 shows a possible embodiment of an identification pattern at the rear side of an electronic circuit.

FIG. 7, 8, 9 show further possible embodiments for identification patterns at the rear side of an electronic circuit.

### DETAILED DESCRIPTION

The invention relates to an improved electronic circuit, in which an identification pattern is applied by means of an inventive adaptation of present characteristics. In this way, no or hardly no time gets lost (and/or extra cost is generated) during the production process, without the advantages of the used characteristics being lost or even reduced. This improvement is indeed directly applicable to the so-called substrates or panels consisting of several of the electronic circuits. These panels are mainly used for transporting and/or selling the circuits in batch. Moreover, the invention also allows to easily adapt the production process of the substrates/circuits to guarantee the identifiability of the circuits.

Unless otherwise specified, all terms used in the description of the invention, including technical and scientific terms, shall have the meaning as they are generally understood by the worker in the technical field of the invention. For a better understanding of the description of the invention, the following terms are explained specifically.

“A”, “an” and “the” refer in the document to both the singular and the plural form unless clearly understood differently in the context. “A segment” means for example one or more than one segment.

When “approximately” or “about” are used in the document together with a measurable quantity, a parameter, a period or moment, etc., variations of +/−20% or less, preferably +/−10% or less, more preferably +/−5% or less, still more preferably +/−1% or less, and even still more preferably +/−0.1% or less than and of the cited value are meant, as far as such variations apply to the invention that is described. It will however be clearly understood that the value of the quantity at which the term “approximately” or “about” is used, is itself specified.

The terms “include”, “including”, “consist”, “consisting”, “provide with”, “contain”, “containing”, “comprise”, “comprising” are synonyms and are inclusive of open terms that indicate the presence of what follows, and that do not exclude or prevent the presence of other components, characteristics, elements, members, steps, known from or described in the state of the art.

The term “practically unique identifier” refers to an identifier for a product that in practice is made uniquely for a particular edition or a number of equal products. Because the term “unique” is too final, and can never be fully guaranteed, it is supplemented with “practically” to indicate the context. Thus, in practice, for the production of a particular electronic circuit, a practically unique identifier can for example comprise at least 20 bits (dependent on the edition). As shown further in this document, it is easy to generate millions or even billions of separate identifiers without much influence on other aspects of the circuit.

The term “retraceable” and “retraceability” refer to the possibility to retrace a history of a product. This history can have a variable extent depending on the product, and can for example comprise: time of production/production steps, identification of raw materials (supplier, batch, characteristics, . . . ), devices used in the production, possible subcomponents of apparatus used at the production that specifically work on the product, error control data about product and/or groups of products, but is not limited thereto. On the contrary, all possible information that can be registered and used for later analysis of the production process in all its aspects, is appropriate thereto and is desirable.

The citation of numeric intervals by means of end points includes all integers, fractions and/or real numbers between the end points, including these end points.

In a first aspect, the invention relates to an electronic circuit, preferably a directly bonded copper (DBC) ceramic substrate circuit for use in power electronics, comprising:
a. a substantially flat, ceramic support layer;
b. a metal layer at at least one side, preferably at both sides, of the ceramic support layer;
   in which at least one metal layer is provided with one or more dimples in the metal layer along at least one edge of the metal layer, in which the dimples are adapted for at least partially reducing tensile forces in the metal layer;
   characterised in that the one or more dimples form an identification pattern, preferably in which the identification pattern distinguishes the electronic circuit from other electronic circuits.

Dimples (holes, dimples, indentations, . . . ) are in some cases made in metal layers of electronic circuits to reduce tensile stress, resulting from the manipulation of two materials with strongly different thermal expansion coefficients (ceramic support layer and metal layer) at the production. The metal layer is applied at high temperature, solidifies and subsequently further shrinks when cooling down, providing tensile stresses with the substantially invariable ceramic support layer onto which the metal layer is applied. To compensate this, dimples have been made. These tensile stress can lead to delamination (and loosing of the metal layer from the ceramic support layer), and thus to critical failure of the electronic circuit. The dimples appear as a succession of holes in the metal layer along the edge of the metal layer, considering the tensile stress can be high at this location. The dimples are moreover often applied to each metal layer of the substrate (for two-sided substrates coated with metal material, but also when at one side of the substrate, several separate surfaces are in metal), considering the tensile stress can be high there each time. For more information about some physical characteristics (dimensions, shape, location and similar) of these dimples, we also refer to amongst other things U.S. Pat. No. 8,350,369, U.S. Pat. No. 6,638,592, EP 1,061,783 or JP 3,192,911.

The applicant suggest to make use in a practical way of said advantages which these dimples offer, and that can also certainly be necessary in high-quality circuits, and to make the dimples in a particular identification pattern at at least one side of the circuit. Considering that at one side, the components are often placed and it will not always be possible to form all possible desirable identification patterns with the dimples, it is in the case of two-sided circuits coated with copper even more interesting, as the ‘rear side’ of the circuit, with the copper side that is not provided with components, is extremely appropriate for making the dimples in a pattern. As in the industry, these dimples can be made along the edges of the metal layer, but they can also have other shapes or take other places (more centrally, double lines, threefold or more, . . . ).

The metal layer (or layers) is typically formed by a metallisation that is bonded to the ceramic support layer via a heating process. At this heating process, the metal layer will settle at an increased temperature. After cooling-down, the metal will shrink (for copper, the linear thermal expansion coefficient at 20° C. is about 17·10⁻⁶ per Kelvin). The ceramic support layer will be less subject to expansions and/or shrinking as the metal is heated in the binding process (copper is hereby typically heated to temperatures higher than 1000° C.). Moreover, typical materials of which the substrate is made (e.g. silica or alumina oxide) are much less sensitive to expansion and shrinking through temperature modifications (for silica, the thermal expansion coefficient at 20° C. is about only 2.6·10⁻⁶ per Kelvin, for alumina oxide about 8.1·10⁻⁶ per Kelvin, also for other types of wafer/support, this coefficient is significantly lower than that of the metal layer). Thus, in case of significant cooling-down, a substantial difference in length can occur at the different layers that are bonded to each other. Thus, the cooling-down produces tensile stresses as a result of the different shrinkings of the layers composing the circuit. These stress can warp the substrate and weaken it so that cracks occur (more easily), before, during or after use of the circuit. In order to limit such losses (these losses also already occur in successive production processes), the dimples were proposed and introduced. Moreover, cracks often occur when singulating the circuits from the circuit, as a result of which this occurs (almost) at the end of the production process, which leads to a significant reduction in productivity and material losses.

By reducing the amount of metal at particular places, the metal will, during and after the cooling-down, cause less stress at the underlying ceramic support layer, which increases the lifetime of the circuit. These reductions in metal are applied as so-called ‘dimples’, a pattern of holes along the edges of the metal layer (with a diameter of about 0.5 mm, although variations thereto are certainly possible; the same goes for the depth of the dimples, also because they also depend on the thickness of the metal layer), as well as the shape. Moreover, in case several rows of dimples occur along one and the same edge, one can also opt for differences in diameter and/or depth and/or spacing between the dimples. The rows of dimples closer to the edge of the metal layer preferably have a larger diameter than those further from the edge. In this context, we refer again to the above-mentioned patent documents, in which one single or several series of ‘dimples’ are present along the edges of the metal layer of the circuit (see also the figures of document U.S. Pat. No. 8,350,369 B2) for reducing the tensile stresses between the layers of the circuit. The advantages thereof are discusses in detail in amongst other things U.S. Pat. No. 6,638,592 B1.

The applicant noticed that in certain markets of electronic products, it is very important that there is a (preferably simple, cheap) traceability for products, especially in case of problems such as sudden cracks. By providing this traceability of (whether or not) defective products, all products of the panel or substrate to which the defective product belonged, and/or that were treated by the same installation, and/or that were produced from one and the same batch of material, . . . can for example also be detected and for example called-back to avoid future problems, as well as to carry out further analysis to avoid, reduce and/or trace/predict the problem in the future. In this way, production processes can be optimized, defective (or anomalous) production devices/systems can be detected quickly. These steps allow to produce at lower cost, as to both the material used and the working hours. Moreover, a consumer can be offered a larger certainty (or lower error margin), which is amongst other things taken into account at larger tenders.

By giving the dimples for the stress reduction a second function, namely as an identifier, the limited space for electronic circuits is used ingeniously, moreover in a very cheap way. As is shown in the figures of said prior art documents, practically a large number of such dimples is present on the circuits. Hereby, a binary pattern can be simply placed (whether or not presence of a dimple at a number of places, or along a whole edge, . . . ) without compromising the effectiveness of the dimples, the reduction of tensile stresses. Indeed, even in case of a reduced number of dimples, for example 100 along the whole edge, the non-occupancy of 2 ‘positions’ (no dimple) can very simply offer 4,950 unique identifiers, the non-occupancy of 3 positions, even 161,700. By working for example with double rows of dimples, there are 196 possible positions then, and with 2 free places, already 19,110 identifiers can be provided, and with 3 open positions more than 1 million. All of this without significant influence on the original function of the dimples. Moreover, as a compensation, additional dimples can be provided so that the intended effect of reduction of the tensile stresses is sufficiently realized. Moreover, along only one edge of the metal layer, dimples can be provided, or symmetrically at opposing edges.

In general, one can choose to identify an electronic circuit in different ways with the identifiers. This can be done in a unique way per substrate to which the circuit belongs, but also in a unique way as a circuit as such (considering the large amount of unique identifiers that can be produced by for example leaving 6 out of 100 positions free: 1,192,052,400; or leaving 10 out of 100 positions free: 17,310,309,456,440). Both cases will be each further discussed later in this document.

A further advantage of this identification is that during the production process, each circuit can also be ‘recognized’ relatively easily by the machines working onto it. The identification patterns are preferably easy to ‘read’ by the machines. In this way, for each circuit, information can be registered in a correct way, by associating it with the identification pattern (and a possible other identifier). This information can deal about information (supplier, batch number, . . . ) of raw materials or subcomponents, the operator, the specific machine or part of the machine and other.

Moreover, it should be noted that the identification patterns can not only be read or recognised visually, but also in a non-visual way. This offers amongst other things advantages if the circuits are mounted, soldered or glued in a casing or attached in any other way, or even completely covered. By for example making use of X-ray or Scanning Acoustic Microscopy (SAM), the identification patterns can still be visualised and thus the circuits can be ‘recognized’. This allows to read the identification pattern in a non-destructive way, which amongst other things can be useful for later problems, considering the circuits can then typically already be part of a larger assembly or device. Known systems or methods for identifying circuits sometimes provide a label, such as a bar code or QR code on the circuits, that are not visible any more or difficult to read once the circuit has been installed.

In a preferred embodiment, the identification pattern of the electronic circuit forms a practically unique identifier for the electronic circuit and in which this practically unique identifier can distinguish the electronic circuit practically in a unique way from at least 2⁵, or rather 2¹⁰, and preferably 2¹⁵, more preferably 2²⁰, still more preferably at least 2²⁵ and even still more preferably 2³⁰, other electronic circuits with their own identification patterns as practically unique identifier. In theory, a less unique identification pattern can be chosen than in the preferred situations described below, in which the circuits then only have to be identified per substrate (panel in which the circuits start, and sometimes also end, the production). Typically, the substrate will then also comprise a separate identifier, for example a QR code, bar code and/or identification number.

In a preferred embodiment, the dimples are provided along edges of the metal layer, preferably over one line per edge of the metal layer in which the line per edge is parallel to the edges of the metal layer. Other options are that more lines or rows of dimples extend parallel to each other along the edge, as a result of which a larger number of identification patterns can be provided and a sufficient tensile stress-reducing effect can be guaranteed.

In a preferred embodiment, a multitude of identification positions are provided along the edges of the metal layer, and the identification pattern is defined by the occupancy and/or non-occupancy of the identification positions with a dimple, preferably in which the successive identification positions have a spacing between 200 μm and 2000 μm. ‘Spacing’ refers to the distance between the centres of successive dimples. As this is the positioning of tensile stress-reducing dimples used in practice, it is also logical and effective to keep the distances as recommended above. Therefore, preferences are also known that depend especially on the thickness of the copper layer (metal layer). Thus, for a copper layer with a thickness of about 300 μm, a spacing of about 800 μm, or between 700 and 900 μm, is typically used, in which the dimples have a diameter of about 600 μm, or between 500 and 700 μm, and preferably about 500 μm, or between 400 and 600 μm, for a dimple in a corner of a circuit. By moreover applying the identification pattern on a certain number of identifications positions, which amounts to being occupied or not by dimples of the identification positions, it is easy to read the identification patterns in an automated way, as it deals about a limited number of positions that are moreover preferably situated at fixed places on the circuit.

In the following, the term “identification positions” should somehow be defined for this document. Hereby, one assumes that in a ‘normal’ circuit with tensile stress-reducing dimples along the complete edge, each of the dimples indicates the location of an identification position. In a preferred embodiment, at least 25%, preferably at least 50%, of the identification positions is occupied by a dimple, more preferably in which at least 33% van the identification positions along each edge separately are separately occupied by an dimples, and in which the identification pattern has a binary representation as a result of the occupancy and/or non-occupancy of the identification positions with the dimples. Still more preferably, at least 60%, 65%, 70%, 75%, 80%, 85%, 90%, 95% or more of the identification positions is occupied by a dimple. Possible minimal occupancy percentages are for example 61%, 62%, 63%, 64%, 66%, 67%, 68%, 69%, 71%, 72%, 73%, 74%, 76%, 77%, 78%, 79%, 81%, 82%, 83%, 84%, 86%, 87%, 88%, 89%, 91%, 92%, 93%, 94%, 96%, 97%, 98%, 99%. The main effect thereof is that in this way, it is sufficiently guaranteed that the original effect of the dimples, the reduction of tensile stress, is realized sufficiently. Note that it is possible to effectively use only a limited number of the above-said identification positions, in other words, in which the possible positions of the dimples only have to be read in a limited number of positions (for example a central band of N positions). In that case, one can of course make an exception to the above-said preferred embodiment as the definition of identification position differs in that case.

In a preferred embodiment, at least one of the identification positions along at least one edge is not occupied by a dimple. Note that one can also choose to carry out these non-occupied position at two (whether or not opposing) edges, or at 3 or 4 edges (or even more preferably at non-square circuits). Moreover, typically, at least 2 (or 3, 4 or more) of the identification positions will not be occupied along at least one edge in order to create a clearer identification pattern in this way.

Preferably, the at least one non-occupied identification position is situated between identification positions of the at least one edge occupied by dimples. Note that this does not necessarily mean that the adjacent identification positions are occupied. In other words, this means that the non-occupied identification position(s) most preferably are not situated at the ends of the edge, in order not to create any confusion, but that this will be ‘internal’ non-occupied positions. Generally, one can also say that maximum 90% of the identification positions along at least one edge can be occupied by a dimple. These remarks apply to both the circuit according to the invention separately, and a substrate comprising a multitude of circuits.

In a preferred embodiment, the metal layer at the level of the dimples has a volume reduction between 10% and 100%, preferably between 30% and 80%, with respect to the metal layer without dimples, preferably so that the dimples have a depth of at least 50 μm with respect to the surrounding plane of the metal layer. The dimples preferably not to completely extend to the ceramic support layer, as this can lead to delamination. Possible maximum depths of the dimples (however, depending on the thickness of the metal layer) are 100 μm, 150 μm, 200 μm, 250 μm, 300 μm, 400 μm, 500 μm or more.

As to the diameter, one chooses for at least 300 μm and maximum 1500 μm, preferably depending on the thickness of the metal layer. Typically, a thickness of the copper layer (metal layer) of about 0.30 mm is chosen for a diameter of the dimples of about 600 μm, or between 500 and 700 μm, and preferably about 500 μm, or between 400 and 600 μm, for a dimple in a corner of a circuit.

In this way, not only the conditions are met to have the tensile stress-reducing effect on the circuit, but it is moreover also possible and easier to observe the identification patterns. The shape and dimensions of the dimples are such that they can realize the tensile stress-reducing effect on the circuit in an optimal way, as has been described above. The dimples can have the shape of a segment of a sphere, a paraboloid shape, a cylindrical cut of other. By not using a complete (100%) reduction as a measure, for example maximum 80%, the process of providing dimples is also much easier, and this is possible for example via a simple laser treatment (laser etching). Also, the zone between successive dimples can undergo a volume reduction with respect to the general metal layer around.

Possible values for the volume reduction are furthermore 20%, 25%, 35%, 40%, 45%, 47.5%, 50%, 52.5%, 55%, 57.5%, 60%, 65%, 70%, 75%, 85%, 90%, 95% or any value in between. As said, the dimensions of the dimples are also partially dependent on the dimensions of the circuit itself (thickness metal layer for example), and thus dimples with a thickness of 20 μm, 25 μm, 30 μm, 35 μm, 40 μm, 45 μm, 55 μm, 60 μm, 65 μm, 70 μm, 75 μm, 80 μm, 85 μm, 90 μm or any other values (in between) are also possible. The same remark applies to the radius (width) of the dimple, that can vary, and can have values such as 75 μm, 80 μm, 85 μm, 90 μm, 95 μm, 100 μm, 105 μm, 110 μm, 120 μm, 130 μm, 140 μm, 150 μm, 160 μm, 170 μm, 180 μm, 190 μm, 200 μm, 225 μm, 250 μm, 275 μm, 300 μm, 325 μm, 350 μm, 375 μm, 400 μm, 425 μm, 450 μm, 475 μm, 500 μm, 550 μm, 600 μm, 650 μm, 700 μm, 750 μm, 800 μm, 850 μm, 900 μm, 950 μm, 1000 μm, or any other value (in between).

In a preferred embodiment, along at least one edge (1, 2, 3, 4 or more at non-square circuits) of the metal layer, two or more (3, 4, 5, 6, 7, 8, 9, 10, . . . ) parallel rows of dimples are provided for forming the identification pattern. As said above, this offers the certainty that the tensile stress-reducing effect of the dimples is achieved, and this offers moreover more possibilities for applying an identification pattern. One the one hand, this offers more possibilities for unique identification patterns, but on the other hand, this also offers the possibility for applying clearer (easier to read) patterns, because larger ‘structures’ can be brought into the pattern, without reducing the effect of the dimples.

In a second aspect, the invention relates to a substrate, preferably for use in power electronics, comprising:
a. a substantially flat, ceramic support layer comprising at least two separate electronic circuits that are connected along a weakened break line;
b. a metal layer on the separate electronic circuits at at least one side, preferably at both sides, of the ceramic support layer, in which the metal layer of the separate electronic circuits are separated along the break lines;
   in which one metal layer of at least one, preferably each, of the electronic circuits of the substrate is provided with one or more dimples in the metal layer along at least one edge of the metal layer, in which the dimples are adapted for at least partially reducing tensile stresses in the metal layer; and in which the one or more dimples per electronic circuit form an identification pattern, in which the identification pattern distinguishes the electronic circuit in a unique way from at least the other electronic circuits of the substrate. Similar extensions as for the separate circuits will hereby be possible for the whole substrate and should be considered as implicitly being part of the text.

As is the case for the separate electronic circuits discussed earlier, here too, the principle of the traceability of the separate electronic circuit is very important, both during the production process and after sale or transport. In this way, problems in the supply chain, in the raw materials and similar can be detected and solved optimally. The arguments described in this document relating to the advantages when using the inventive concept in electronic circuits, obviously also apply to the application thereof at a substrate of several circuits.

In this document, we will not further discuss the general characteristics of such substrates of electronic circuits, as they are largely known, and are considered as implicitly part of the patent application. Only the aspects that are relevant for understanding the said invention, will possible be further discussed in the text below. The possible embodiments of the electronic circuits, or substrates with electronic circuits are in no way limited to these shown in the figures, but can be considered as belonging to the know-how of an expert in the domain of (power) electronics.

As is shown in the figures, all electronic circuits of the substrate are provided with an identification pattern that identifies them at least in a unique way with respect to the other circuits of the substrate.

In a preferred embodiment, the substrate is provided with a substrate identification for identifying the substrate in a practically unique way, preferably a one-dimensional or two-dimensional bar code, such as a bar code or a QR code. This allows not to only have to provide the circuits with a unique identification pattern with respect to all other (similar) circuits, but only with respect to the circuits in the same substrate. In this way, much more simple and better readable identification patterns can be used for the separate circuits themselves, that indicate for example the relative position of the circuit in the substrate. The position of such a substrate identification can be realized in different ways, for example on so-called “waste borders” (see also in the figures).

Alternatively, the circuits can of course also be provided with a unique identification pattern making the substrate identification superfluous. In a preferred embodiment, the identification pattern of each electronic circuit forms a practically unique identifier for the electronic circuit and in which the practically unique identifier can distinguish the electronic circuit in a practically unique way from at least 2²⁰, preferably 2²⁵, more preferably 2³⁰, other electronic circuits with the identification patterns as practically unique identifier.

In a preferred embodiment, for each electronic circuit, the dimples are provided along edges of the metal layer, preferably over one line per edge of the metal layer in which the line per edge is parallel to the edges of the metal layer. Alternatively, more lines or rows of dimples are provided along one or more edges of the metal layer. These several lines or rows per edge can be positioned in a crossed way.

In a preferred embodiment, for each electronic circuit, a multitude of identification positions are provided along the edges of the metal layer, and in which the identification pattern is defined by the occupancy and/or non-occupancy of the identification positions by a dimple, preferably in which the successive identification positions have a spacing between 200 μm and 2000 μm. In this context, we refer to what has been described for the separate circuits.

In a preferred embodiment, for each electronic circuit, at least 25%, preferably at least 50%, of the identification positions is occupied by a dimple, more preferably in which at least 33% van the identification positions along each edge separately are occupied by an dimples, and in which the identification pattern has a binary representation as a result of the occupancy and/or non-occupancy of the identification positions with the dimples. Still more preferably, at least 70%, 75%, 80%, 85%, 90%, 95% or more of the identification positions is occupied by a dimple. Possible minimal occupancy percentages are for example 61%, 62%, 63%, 64%, 66%, 67%, 68%, 69%, 71%, 72%, 73%, 74%, 76%, 77%, 78%, 79%, 81%, 82%, 83%, 84%, 86%, 87%, 88%, 89%, 91%, 92%, 93%, 94%, 96%, 97%, 98%, 99%. The main effect thereof is that in this way, it is sufficiently guaranteed that the original effect of the dimples, the reduction of tensile stress, is realized sufficiently.

In a preferred embodiment, the substrate relates to a directly bonded copper (DBC) ceramic substrate. Such substrates are especially popular in power electronics because of their especially good characteristics in the domain of thermal conductivity. However, despite the good values, temperature modifications occur quite often, which can again lead to (often smaller) tensile stresses. Because of the presence of dimples, they are however rarely problematic, but it makes such DBC substrates excellent candidates for the proposed invention, as the dimples are already present in most embodiments thereof, and it thus requires only a small adjustment to make the circuits identifiable.

In a preferred embodiment, the metal layer at the level of the dimples has a volume reduction between 10% and 100%, preferably between 30% and 80%, with respect to the metal layer without dimples, preferably so that the dimples have a depth of at least 50 μm with respect to the surrounding plane of the metal layer and have a radius of in average at least 100 μm. Possible values for the volume reduction are furthermore 20%, 25%, 35%, 40%, 45%, 47.5%, 50%, 52.5%, 55%, 57.5%, 60%, 65%, 70%, 75%, 85%, 90%, 95% or any value in between. As said, the dimensions of the dimples are also partially dependent on the dimensions of the circuit itself (thickness metal layer for example), and thus dimples with a thickness of 20 μm, 25 μm, 30 μm, 35 μm, 40 μm, 45 μm, 55 μm, 60 μm, 65 μm, 70 μm, 75 μm, 80 μm, 85 μm, 90 μm or any other values (in between) are also possible. The same remark applies to the radius (width) of the dimple, that can vary, and can have values such as 75 μm, 80 μm, 85 μm, 90 μm, 95 μm, 100 μm, 105 μm, 110 μm, 120 μm, 130 μm, 140 μm, 150 μm, 160 μm, 170 μm, 180 μm, 190 μm, 200 μm, 225 μm, 250 μm, 275 μm, 300 μm, 325 μm, 350 μm, 375 μm, 400 μm, 425 μm, 450 μm, 475 μm, 500 μm, 550 μm, 600 μm, 650 μm, 700 μm, 750 μm, 800 μm, 850 μm, 900 μm, 950 μm, 1000 μm, or any other value (in between).

The advantages thereof have already been discussed for the separate circuits, and thus also apply in general to the substrate.

In a third aspect, the invention relates to a method for applying tensile force-reducing identification patterns on a metal layer of a substrate, in which the substrate comprises a multitude of electronic circuits, comprising the following steps:
a. providing the substrate, in which the electronic circuits comprise a metal layer at at least one side of a ceramic flat support layer;
b. applying one or more dimples in the metal layer along at least one edge of the metal layer, in which the dimples are adapted for at least partially reducing tensile forces in the metal layer;
   in which one or more dimples are applied in an identification pattern, preferably in which the identification pattern distinguishes the electronic circuit at least in a unique way from the other electronic circuits of the substrate;
c. and coupling the electronic circuits to the applied identification pattern in a central server.

Hereby, all possible adjustments to the identification pattern as described in the present document can be applied to the method as described above. The advantages that have already been discussed in the embodiments and products themselves, logically also apply to the method. By applying the identification pattern as suggested, an identification component is avoided (cheaper) and the action of making the circuits/substrates identifiable must not be carried out separately any more, and this is simply part of a step that normally already is part of the production process.

In a further aspect the method comprises the following steps:
a. producing the substrate along a production line with one or more production devices, in which the substrate is produced with one or more raw materials from identifiable batches of the one or more raw materials;
b. applying a tension-reducing identification pattern on a metal layer of the substrate according to the above-described method;
c. centrally storing information relating to the production line and/or the production devices and/or the identifiable batch of the raw materials, that are used in the step of producing the substrate.

Hereby, all possible adjustments to the identification pattern as described in the present document can be applied to the method as described above. By applying an identification pattern as described in the present document, it is, as said, possible to carry out an intensive error analysis and to optimize the production process.

In a fourth aspect, it relates to a use of one or more dimples as identification pattern for an electronic circuit, in which the electronic circuit comprises a substantial flat, ceramic support layer, and a metal layer at at least one side, preferably at both sides, of the ceramic support layer, in which at least one metal layer is provided with the dimples in the metal layer along at least one edge of the metal layer, and in which the dimples are adapted for at least partially reducing the tensile stresses in the metal layer; preferably in which the identification pattern distinguishes the electronic circuit from at least other electronic circuits in a same substrate as the electronic circuit, and more preferably in which the electronic circuit relates to a directly bonded copper (DBC) ceramic substrate circuit for use in power electronics.

Preferably, the electronic circuit is part of a substrate according to the invention.

Note that these steps can be carried out in an arbitrary order (and/or simultaneously), if practically possible.

In the following, the invention will be described by means of non-limiting examples illustrating the invention, and not meant to be interpreted as limiting the scope of the invention.

### EXAMPLES

The applicant wishes to notice that only a number of possible embodiments of the identification patterns is shown in the figures and discussed in the examples, but that all modifications thereof should be considered as part of the invention and implicitly are part of the present document, as they all fall under the invention described herein. Further, one should notice that the identification patterns are preferably applied onto the metal layer at the rear side of the electronic circuit as the components at the front side can possibly make the application of a pattern impossible and/or can reduce the readability of the identification pattern. The applicant does however not reject the possibility that the front side (whether or not together with the rear side) of such identification pattern is provided. On the other hand, the front side can be provided with the dimples without an identification pattern being applied herein.

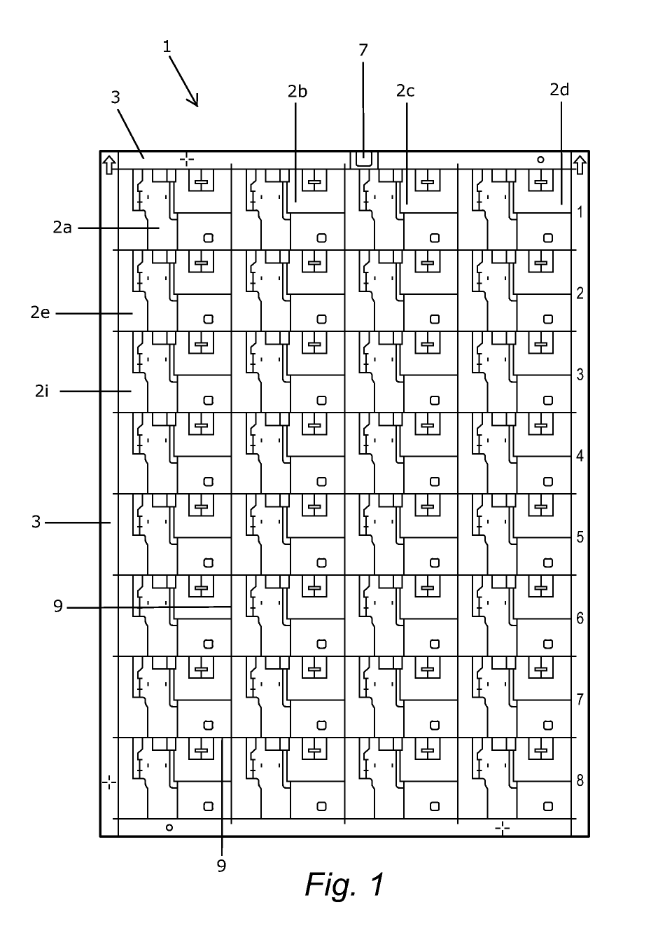

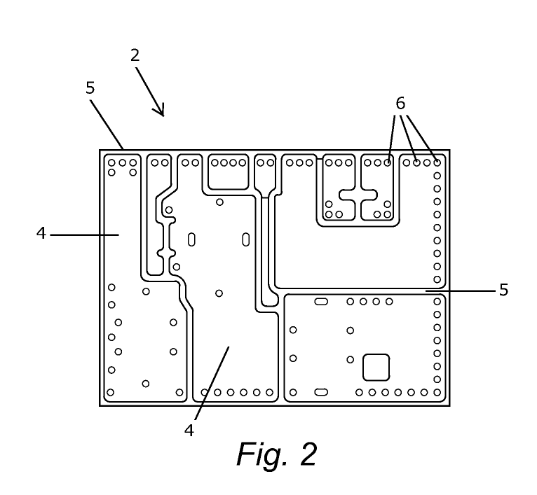

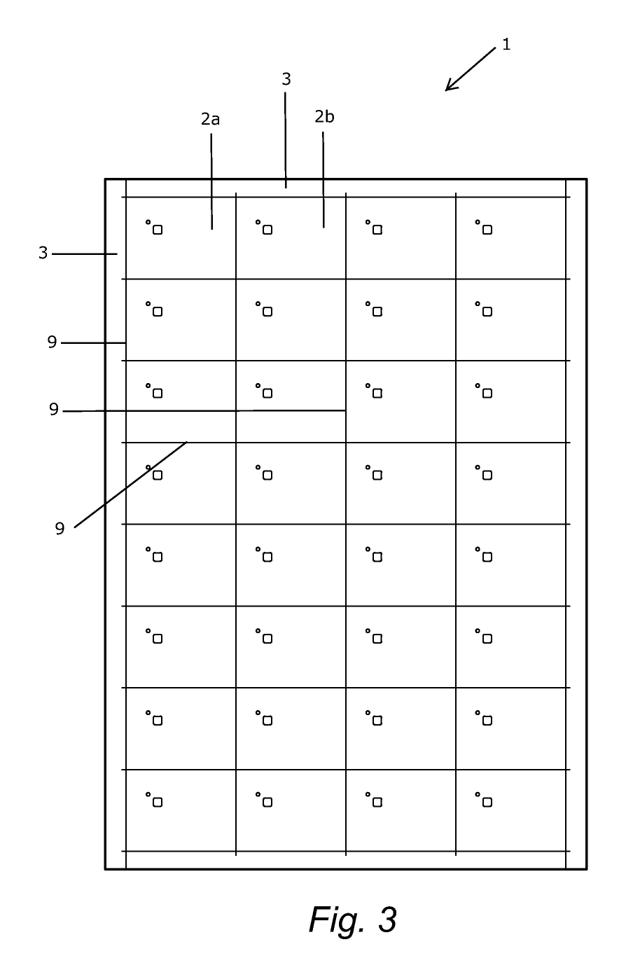

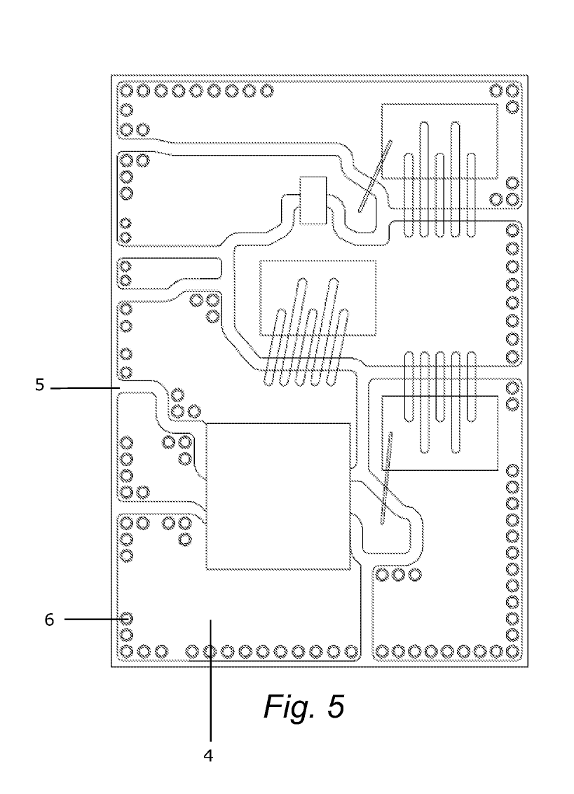

FIG. 1 shows a general view of the front side of a substrate (1) with electronic circuits (2a, 2b, 2c, . . . ), composed of a ceramic support layer (5) with thereupon a metal layer (4), whether or not at the front and rear side. The substrate (1) comprises in this case a grid of 4 out of 8 electronic circuits (2a, 2b, 2c, . . . ), that can be broken off from each other along predetermined break lines (9). This are weakened parts in the ceramic support layer (5) of the substrate between the separate circuits (2a, 2b, 2c, . . . ). Furthermore, a substrate (1) comprises mostly one or several breakable edges or ‘waste borders’ (3) that amongst other things serve to clamp and move the substrate (1) without causing damage to the circuits (2). Optionally, a substrate identification (7) can be applied to such a breakable edge (3). FIG. 2 shows a possible view of the front side of a separate electronic circuit (2) without components, FIG. 5 shows the same with additional components and connections. As is shown in these figures, the front side of the electronic circuit (2) composes of a ceramic support layer (5) with thereupon a number of islands of the metal layer (4). These islands of the metal layer (4) can be provided along the edges with dimples (6), for reducing the tensile stress. Optionally, they can also further serve as an identification pattern (whether or not combined with an identification pattern at the rear side of the electronic circuit). FIG. 3 shows a general view of the rear side of a substrate (1) with electronic circuits (2a, 2b, . . . ). The breakable edges (3) and break lines (9) are hereby also clearly shown. Note that the break lines are not necessarily provided along both sides in the ceramic support layer.

### Example 1

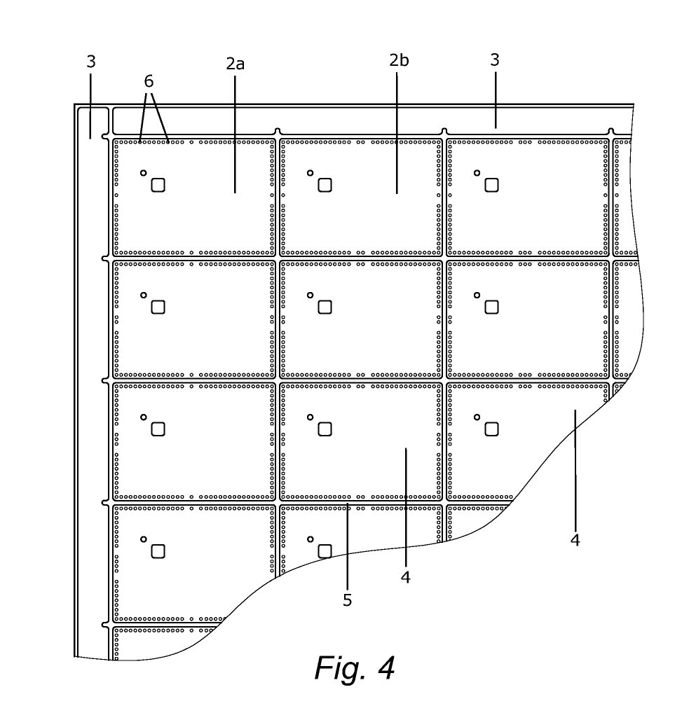

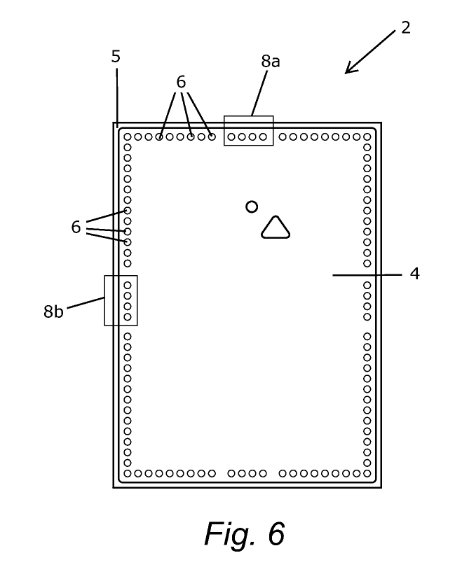

In a first example, a single row of dimples (6) is provided along the edges of the metal layer (4) of each circuit (2). In this variant, the substrate (1) has a substrate identification (7) in the form of a QR code. The identification pattern of the dimples (6) is thus provided for indicating the position of a circuit in a substrate (1). For reasons of simplicity, we have here opted for that the upper and lower series of dimples on a circuit has a central ‘free’ island (8a) with dimples that indicate in which column of the substrate the circuit is located. The left and right series of dimples of a circuit also has a central free island (8b) with dimples that indicate in which row of the substrate the circuit is located. In this example, it is indicated by the number of dimples of which the central free island is composed. This is clearly indicated in FIG. 6, in which the upper series 4 comprises dimples in the central island (8a), as well as the left series that comprises 4 dimples in the central island (8b), and indicates that the circuit (in this way of arranging the identification pattern) was in the fourth row and fourth column of the substrate for singulation. A general view thereof is shown in FIG. 4.

### Example 2

Alternatively, a succession of dimples can be read as a binary code (in which they occur at fixed intervals or not, a possible dimple can be read as a ‘1’, an absence as a ‘0’ and vice versa). The position of the first ‘bit’ or start bit can be fixed deliberately, or a more general convention can be laid down in this context, as well as a reading direction (clockwise or counter-clockwise). Again referring to FIG. 6, in which the start bit is placed in the upper left corner and is read in clockwise direction, the 108 bits of the binary code are: 111111111 0 1111 0 111111111 111111111111 0 1111 0 111111111111 111111111 0 1111 0 111111111 111111111111 0 1111 0 111111111111. In this way, also FIG. 4 can be completely interpreted again with respect to example 1. As said, subsequently minimal conditions can be laid down here, such as a minimal occupancy with dimples for the code. Even with a minimal occupancy of 92.5% (maximum 8 ‘holes’ or unoccupied places), this offers the option for 352,025,629,371 unique codes. In this way, a substrate identification is no longer necessary, and the production process of specific circuits can still be found more easily.

### Example 3

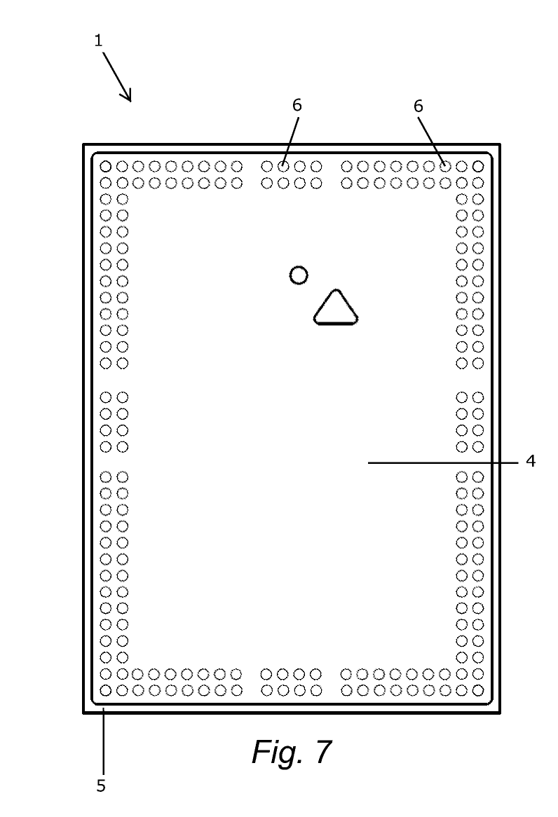

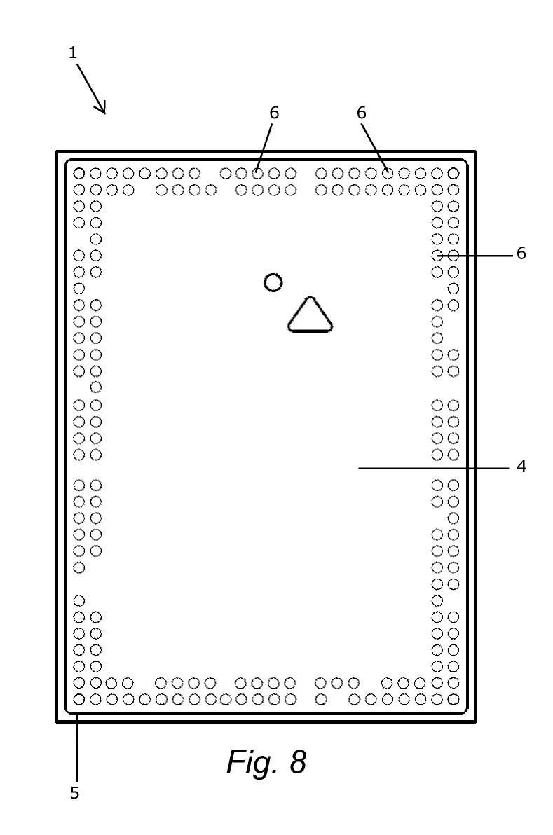

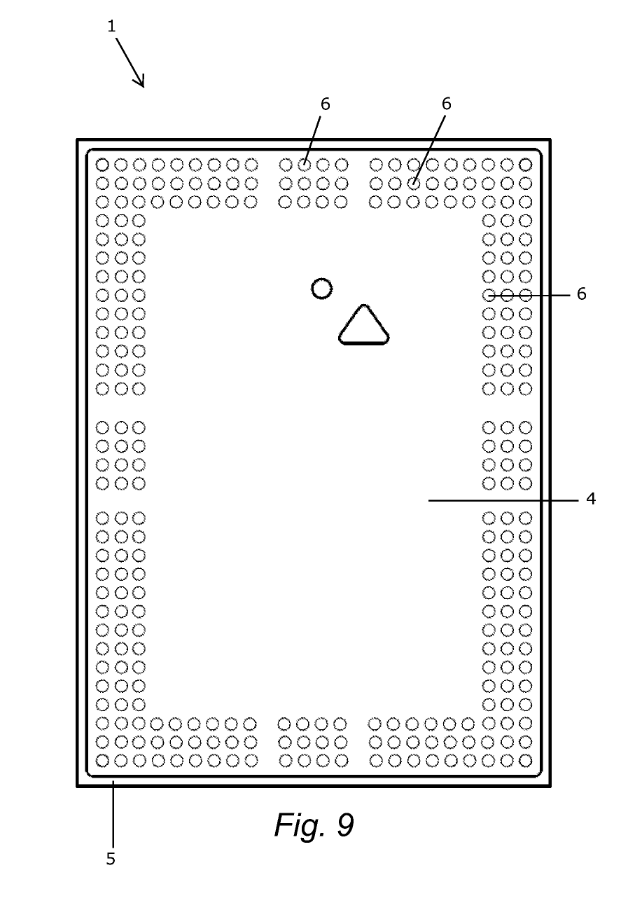

In this embodiment, shown in FIG. 7 or FIG. 8, a double row of dimples is provided. The double rows can indicate the same pattern, as in FIG. 7 (for increased readability) or different pattern, as in FIG. 8 (for more unique identification patterns). The way in which the identification patterns can be read (see examples 1 and 2) vary and are dependent on the choice of a user. Nevertheless, the applicant considers possible variations (triple rows as in FIG. 9, crossed double/triple rows, asymmetry, . . . ) on patterns also as part of this document, as it is based on the same basic idea.

It will be understood that the present invention is not limited to the embodiments described above and that some adjustments or changes can be added to the described examples without changing the scope of the enclosed claims. The present invention has for example been described with reference to electronic circuits for power electronics, specific so-called DBC substrates and circuits, but it will be clear that the invention can also be applied to all kinds of circuits comprising several layers between which tensile stress can occur at the production and in which identifiability of the concerned circuits is desired.

1. Electronic circuit, preferably a directly bonded copper (DBC) ceramic substrate circuit for use in power electronics, comprising:
a. a substantially flat, ceramic support layer;
b. a metal layer at at least one side, preferably at both sides, of the ceramic support layer;
in which at least one metal layer is provided with one or more dimples in the metal layer along at least one edge of the metal layer, in which the dimples are adapted for at least partially reducing tensile forces in the metal layer;
wherein said one or more dimples form an identification pattern, preferably in which the identification pattern distinguishes the electronic circuit from at least other electronic circuits in a same substrate as the electronic circuit.

2. Electronic circuit of claim 1, in which the identification pattern of the electronic circuit forms a practically unique identifier for the electronic circuit and in which this practically unique identifier can distinguish the electronic circuit in a practically unique way from at least 2²⁰, preferably 2²⁵, more preferably 2³⁰, other electronic circuits with such identification patterns as practically unique identifier.

3. Electronic circuit of the claim 1, in which the dimples are provided along edges of the metal layer, preferably over one line per edge of the metal layer in which the line per edge is parallel to the edges of the metal layer.

4. Electronic circuit of the claim 1, in which a multitude of identification positions are provided along the edges of the metal layer, and in which the identification pattern is defined by the occupancy and/or non-occupancy of the identification positions by a dimple, preferably in which the successive identification positions have a spacing between 200 μm and 2000 μm.

5. Electronic circuit of claim 1, in which a multitude of identification positions are provided along the edges of the metal layer, and in which the identification pattern is defined by the occupancy and/or non-occupancy of the identification positions by a dimple, in which at least one of the identification positions along at least one of the edges is not occupied by a dimple, preferably in which this at least one unoccupied identification position is situated between indication positions that are occupied by dimples of the at least one edge, and in which the identification pattern has a binary representation as a result of the occupancy and/or non-occupancy of the identification positions with the dimples.

6. Electronic circuit of claim 1, whereby the metal layer at the level of the dimples has a volume reduction between 10% and 100% with respect to the metal layer without dimples, preferably so that the dimples have a depth of at least 50 μm with respect to the surrounding plane of the metal layer, and have a radius of in average at least 100 μm.

7. Electronic circuit of claim 1, whereby along at least one edge of the metal layer, two or more parallel rows of dimples are provided for forming the identification pattern.

8. Substrate, preferably for use in power electronics, comprising:
a. a substantially flat, ceramic support layer comprising at least two separate electronic circuits that are connected along a weakened break line;
b. a metal layer on the separate electronic circuits at at least one side, preferably at both sides, of the ceramic support layer, in which the metal layer of the separate electronic circuits are separated along the break lines;
in which one metal layer of at least one, preferably each, of the electronic circuits of the substrate is provided with one or more dimples in the metal layer along at least one edge of the metal layer, in which the dimples are adapted for at least partially reducing tensile forces in the metal layer;
wherein the one or more dimples per electronic circuit form an identification pattern, in which the identification pattern distinguishes the electronic circuit from at least the other electronic circuits of the substrate.

9. Substrate of the previous claim 8, in which the substrate is provided with a substrate identification for the practically unique identification of the substrate, preferably a one-dimensional or two-dimensional bar code.

10. Substrate of any the previous claim 8, in which the identification pattern of each electronic circuit forms a practically unique identifier for the electronic circuit and in which the practically unique identifier can distinguish the electronic circuit in a practically unique way from at least 2²⁰, preferably 2²⁵, more preferably 2³⁰, other electronic circuits with the identification patterns as practically unique identifier.

11. Substrate of the claim 8, in which the dimples for each electronic circuit are provided along edges of the metal layer, preferably over one line per edge of the metal layer in which the line per edge is parallel to the edges of the metal layer.

12. Substrate of the claim 8, in which, for each electronic circuit, a multitude of identification positions are provided along the edges of the metal layer, and in which the identification pattern is defined by the occupancy and/or non-occupancy of the identification positions by a dimple, preferably in which the successive identification positions have a spacing between 200 μm and 2000 μm.

13. Substrate of the previous claim 8, in which at least one of the identification positions along at least one of the edges is not occupied by a dimple, preferably in which this at least one unoccupied identification position is situated between indication positions that are occupied by dimples of the at least one edge, and in which the identification pattern has a binary representation as a result of the occupancy and/or non-occupancy of the identification positions with the dimples.

14. Substrate of the previous claim 8, in which the substrate is a direct bonded copper (DBC) ceramic substrate.

15. Substrate of the previous claim 8, whereby the metal layer at the level of the dimples has a volume reduction between 10% and 100% with respect to the metal layer without dimples, preferably so that the dimples have a depth of at least 50 μm with respect to the surrounding plane of the metal layer, and have a radius of in average at least 100 μm.

16. Use of one or more dimples as identification pattern for an electronic circuit, in which the electronic circuit comprises a substantial flat, ceramic support layer, and a metal layer at at least one side, preferably at both sides, of the ceramic support layer, in which at least one metal layer is provided with the dimples in the metal layer along at least one edge of the metal layer, and in which the dimples are adapted for at least partially reducing the tensile stresses in the metal layer; preferably in which the identification pattern distinguishes the electronic circuit from at least other electronic circuits in a same substrate as the electronic circuit, and more preferably in which the electronic circuit concerns a directly bonded copper (DBC) ceramic substrate circuit for use in power electronics.

17. Use of one or more dimples as identification pattern for an electronic circuit according to the previous claim 16, whereby the electronic circuit is comprised in a substrate.

18. Method for applying tensile stress-reducing identification patterns on a metal layer of a substrate, in which the substrate comprises a multitude of electronic circuits, comprising the following steps:
a. providing the substrate, in which the electronic circuits comprise a metal layer at at least one side of a ceramic flat support layer;
b. applying one or more dimples in the metal layer along at least one edge of the metal layer, in which the dimples are adapted for at least partially reducing tensile forces in the metal layer;
wherein one or more dimples are applied in an identification pattern, preferably in which the identification pattern distinguishes the electronic circuit at least in a unique way from the other electronic circuits of the substrate;
c. coupling the electronic circuits to the applied identification pattern in a central server.

19. Method according to the preceding claim 18:
a. producing the substrate along a production line with one or more production devices, in which the substrate is produced with one or more raw materials from identifiable batches of the one or more raw materials;
centrally storing information relating to the production line and/or the production devices and/or the identifiable batch of the raw materials, that are used in the step of producing the substrate.
